(19) United States
(12) Patent Application Publication
(10) Pub. No.: US 2020/0148064 A1
(43) Pub. Date: May 14, 2020

(54) POWER SUPPLY DEVICE

(71) Applicant: FORD GLOBAL TECHNOLOGIES, LLC, Dearborn, MI (US)

(72) Inventors: Philip Michael GONZALES, Dearborn, MI (US); Stephanie SINGER, Berkley, MI (US); Michael M. MAGOULICK, Livonia, MI (US); John STURZA, Royal Oak, MI (US); Dylan ERB, Allen Park, MI (US); Charles HONICK, Canton, MI (US); Abdul LATEEF, Canton, MI (US)

(21) Appl. No.: 16/189,713

(22) Filed: Nov. 13, 2018

(51) Int. Cl. B60L 50/51; H05K 1/02; G01R 15/20; H01M 10/48; G01R 19/00

(52) U.S. Cl. CPC B60L 50/51; H05K 1/0254; G01R 15/202; H05K 2201/05; G01R 19/0092; B60L 2240/423; H05K 2201/10151; H01M 10/482

(57) ABSTRACT

A vehicle includes an electric machine, a battery, an inverter, and a flexible circuit. The electric machine is configured to propel the vehicle. The inverter is configured to convert direct current from the battery into alternating current. The flexible circuit has a sensor embedded therein that is configured to measure a first phase of the alternating current. The sensor is secured to an output terminal of the inverter that is connected to a first winding phase of the electric machine.

### TECHNICAL FIELD

The present disclosure relates to electric vehicles and power supply devices for electric vehicles.

### BACKGROUND

Electric and hybrid vehicles may include power modules that are configured to convert electrical power from direct current (DC) into alternating current (AC) and/or vice versa.

### SUMMARY

A vehicle includes an electric machine, a battery, an inverter, and a flexible circuit. The electric machine is configured to propel the vehicle. The inverter is configured to convert direct current from the battery into alternating current. The flexible circuit has a sensor embedded therein that is configured to measure a first phase of the alternating current. The sensor is secured to an output terminal of the inverter that is connected to a first winding phase of the electric machine.

A vehicle includes an electric machine, a battery, an inverter, and a flexible circuit. The electric machine is configured to propel the vehicle. The inverter is configured to convert direct current from the battery into alternating current. The flexible circuit has a sensor embedded therein that is configured to measure the direct current of the battery. The sensor is secured to an input terminal of the inverter that is connected to the battery.

A vehicle includes an electric machine, a battery, a rectifier, and a flexible circuit. The rectifier is configured to convert alternating current from the electric machine into direct current. The flexible circuit has a sensor embedded therein that is configured to measure a first phase of the alternating current. The sensor is secured to an input terminal of the rectifier that is connected to a first winding phase of the electric machine.

### BRIEF DESCRIPTION OF THE DRAWINGS

FIG. 1 is a circuit diagram of a power controller illustrating an inverter that is coupled to a DC power source and an electric machine;

FIG. 2 is a circuit diagram of the power controller illustrating a rectifier that is coupled to an AC power source and an energy storage device, such as a battery; and

FIG. 3 is a top view of a power module that includes the inverting and rectifying circuitry.

### DETAILED DESCRIPTION

Embodiments of the present disclosure are described herein. It is to be understood, however, that the disclosed embodiments are merely examples and other embodiments may take various and alternative forms. The figures are not necessarily to scale; some features could be exaggerated or minimized to show details of particular components. Therefore, specific structural and functional details disclosed herein are not to be interpreted as limiting, but merely as a representative basis for teaching one skilled in the art to variously employ the embodiments. As those of ordinary skill in the art will understand, various features illustrated and described with reference to any one of the figures may be combined with features illustrated in one or more other figures to produce embodiments that are not explicitly illustrated or described. The combinations of features illustrated provide representative embodiments for typical applications. Various combinations and modifications of the features consistent with the teachings of this disclosure, however, could be desired for particular applications or implementations.

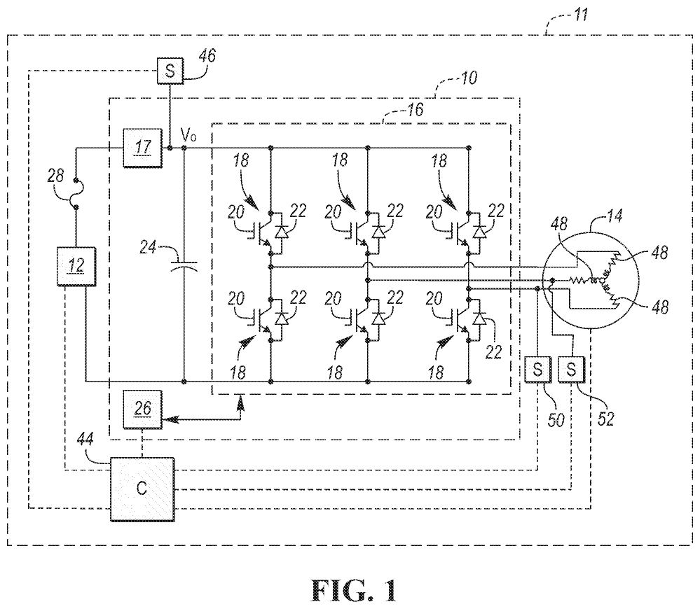

Referring to FIG. 1, a circuit diagram of a power controller (or power supply device) 10 coupled to a power source 12 and an electric machine 14 is illustrated. The electric machine may be an electric motor or a motor/generator combination. The power controller 10 may be utilized in an electric drive system of a vehicle 11, such as an electric or hybrid vehicle. The power source 12 may be coupled to the power controller 10 in order to drive the electric machine 14. In some contexts, including the context of an electric or hybrid vehicle, the power source 12 may be a battery, such as a traction battery, and the electric machine 14 may be an electric motor or an electric motor/generator combination. The power controller 10 may include an inverter 16 and a voltage converter 17. The voltage converter 17 may be DC to DC converter. Alternatively, the voltage converter 17 may be a separate component that is not integral to the power controller 10. The inverter 16 and the voltage converter 17 may be configured to deliver electrical power to the electric machine 14.

The inverter 16 includes inverting circuitry. The inverting circuitry may include switching units 18. The switching units 18 may each comprise a transistor 20, such as an insulated gate bipolar transistor (IGBT), in antiparallel with a diode 22. The switching units 18 may be configured to provide alternating current to the electric machine 14. More specifically, the inverter 16 may be configured to convert direct electrical current provided by the power source 12 into alternating electrical current, which is then delivered to the electric machine 14. The power controller 10 may include a linking capacitor 24. The linking capacitor 24 may be disposed between the power source 12 and the inverter 16. The linking capacitor 24 may be configured to absorb ripple currents generated at the inverter 16 or the power source 12, and stabilize the DC-link voltage, Vo, for inverter 16 control. Stated in other terms, the linking capacitor 24 may be arranged to limit voltage variation at an input of inverting circuitry due to ripple currents generated by the inverting circuitry or a battery, such as a traction battery, that may comprise the power source 12. The power controller 10 may include a drive board 26 for controlling the inverting circuitry. The drive board 26 may be a gate drive board that is configured to operate the transistors 20 of the switching units 18 of the inverter 16 when converting the direct current of the power source 12 into alternating current and delivering the alternating current to the electric machine 14.

The voltage converter 17 may include an inductor. The circuitry of the voltage converter (not shown), including the inductor, may be configured to amplify or increase the voltage of the electrical power being delivered to the electric machine 14 from the power source 12. A fuse 28 may be disposed on the direct current side of the inverter 16 to protect the inverting circuitry from surges in electrical power.

The disclosure should not be construed as limited to the circuit diagram of FIG. 1, but should include power control devices that include other types inverters, capacitors, converters, or combinations thereof. For example, the inverter 16 may be an inverter that includes any number of switching units and not be limited to the number of switching units depicted in FIG. 1. Alternatively, the linking capacitor 24 may be configured to couple one or a plurality of inverters to a power source.

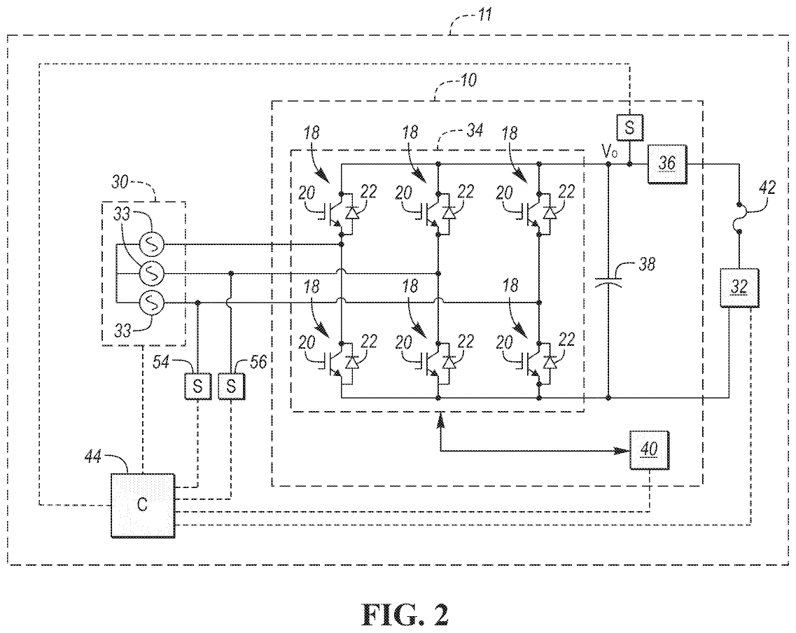

Referring to FIG. 2, a circuit diagram of additional components of the power controller 10 are illustrated. The power controller 10 is further coupled to an AC power source 30 and an energy storage device 32. The AC power source may include three winding phases 33. The energy storage device 32 may be a battery, such as a traction battery, and the AC power source 30 may be an electric generator. The energy storage device 32 and the power source 12 depicted in FIG. 1 may be the same component or may be separate components. The AC power source 30 and the electric machine 14 depicted in FIG. 1 may be separate components. For example, the electric machine 14 may be an electric motor that is configured to propel the vehicle 11 by drawing power from the power source 12, while the AC power source 30 may be an electric generator that is configured to recharge the energy storage device 30 (e.g., during regenerative braking of the vehicle 11 or while being the AC power source 30 is being powered by an additional power source such as an internal combustion engine). Alternatively, the AC power source 30 and the electric machine 14 depicted in FIG. 1 may be the same component, such as a motor/generator combination that is configured to operate as an electric motor under some conditions and as an electric generator under other conditions. The power controller 10 may include a rectifier 34 and a voltage converter 36. The rectifier is an AC to DC converter while the voltage converter 36 may be DC to DC converter. Alternatively, the voltage converter 36 may be a separate component that is not integral to the power controller 10. The rectifier 34 and the voltage converter 36 may be configured to deliver direct current electrical power to the energy storage device 32.

The rectifier 34 includes circuitry that is configured to convert alternating electric current into direct electric current. The rectifier circuitry may include switching units 18. The switching units 18 may each comprise a transistor 20, such as an insulated gate bipolar transistor (IGBT), in antiparallel with a diode 22. The switching units 18 may be configured to provide direct current to the energy storage device 32. More specifically, the rectifier 34 may be configured to convert alternating electrical current provided by the AC power source 30 into direct electrical current, which is then delivered to the energy storage device 32. The power controller 10 may include a linking capacitor 38. The linking capacitor 38 may be disposed between the energy storage device 32 and the rectifier 34. The linking capacitor 38 may be configured to absorb ripple currents generated at the rectifier 34 or the energy storage device 32, and stabilize the DC-link voltage, Vo, for rectifier 34 control. Stated in other terms, the linking capacitor 38 may be arranged to limit voltage variation at an output of rectifier circuitry due to ripple currents generated by the rectifier circuitry or a battery, such as a traction battery, that may comprise the energy storage device 32. The power controller 10 may include a drive board 40 for controlling the rectifier circuitry. The drive board 40 may be a gate drive board that is configured to operate the transistors 20 of the switching units 18 of the rectifier 34 when converting the alternating current of the AC power source 30 into direct current and delivering the direct current to the energy storage device 32.

The voltage converter 36 may include an inductor. The circuitry of the voltage converter (not shown), including the inductor, may be configured to decrease the voltage of the electrical power being delivered to the energy storage device 32 from the AC power source 30. A fuse 42 may be disposed on the direct current side of the rectifier to protect the rectifier circuitry from surges in electrical power.

The disclosure should not be construed as limited to the circuit diagram of FIG. 2, but should include power control devices that include other types rectifiers, capacitors, converters, or combinations thereof. For example, the rectifier 34 may be a rectifier that includes any number of switching units and not be limited to the number of switching units depicted in FIG. 2. Alternatively, the linking capacitor 38 may be configured to couple one or a plurality of rectifiers 34 to an AC power source.

Furthermore, it should be understood that the components of the power controller 10 depicted in FIGS. 1 and 2 may be common or separate components. For example, voltage converter 17 and voltage converter 36 may be the same component or may be separate components, drive board 26 and drive board 40 may be the same component or may be separate components, linking capacitor 24 and linking capacitor 38 may be the same component or may be separate components, fuse 28 and fuse 42 may be the same component or may be separate components, etc.

Referring now to FIGS. 1 and 2, the vehicle 11 further includes an associated controller 44 such as a powertrain control unit (PCU). While illustrated as one controller, the controller 44 may be part of a larger control system and may be controlled by various other controllers throughout the vehicle 11, such as a vehicle system controller (VSC). It should therefore be understood that the controller 44 and one or more other controllers can collectively be referred to as a “controller” that controls various subcomponents of the vehicle 11 in response to signals from various sensors to control functions such as operating the electric machine 14 to generate torque and power to propel the vehicle 11, operating the AC power source 30 to charge a battery (e.g., energy storage device 32), operating an internal combustion engine (if the vehicle 11 is a hybrid vehicle that includes an internal combustion engine in addition to one or more electric machine) to generate torque and power to propel the vehicle 11, etc. The controller 44 may include a microprocessor or central processing unit (CPU) that is in communication with various types of computer readable storage devices or media. Computer readable storage devices or media may include volatile and nonvolatile storage in read-only memory (ROM), random-access memory (RAM), and keep-alive memory (KAM), for example. KAM is a persistent or non-volatile memory that may be used to store various operating variables while the CPU is powered down. Computer-readable storage devices or media may be implemented using any of a number of known memory devices such as PROMs (programmable read-only memory), EPROMs (electrically PROM), EEPROMs (electrically erasable PROM), flash memory, or any other electric, magnetic, optical, or combination memory devices capable of storing data, some of which represent executable instructions, used by the controller in controlling the vehicle 11 and subcomponents thereof.

The controller 44 may be in communication with the power source 12, the electric machine 14, the drive board 26, the AC power source 30, the energy storage device 32, and the drive board 40. In response to a command to provide torque and power to propel the vehicle 11, the controller 44 may operate the power source 12, drive board 26, and electric machine 14 such that the desired power is delivered to the electric machine 14 from the power source 12 via the inverter 16 of the power module 10. The power at various points within the system may be monitored and adjusted via the controller 44 to obtain the desired torque and power output the electric machine 14. The DC power that is being delivered to the inverter 16 may be determined by a first sensor 46 that measures the direct electric current being delivered at an input to inverter 16. The AC power that is being delivered to each winding phase 48 of the electric machine 14 may be determined by a second sensor 50 and a third sensor 52 that measure the alternating electric current being output from the inverter 16 to a first and second of the three winding phases 48, respectively, of the electric machine 14. The alternating electric current and power being output from the inverter 16 to the third winding phase 48 of the electric machine 14 may be estimated based on the measurements of the first two winding phases 48. The controller 44 may include an algorithm that converts the various current measurements to a torque or power being output by the electric machine 14.

In response to a command to recharge the energy storage device 32, the controller 44 may operate the AC power source 30, the drive board 40, and the energy storage device 32 to deliver power from the AC power source 30 to the energy storage device 32 via the rectifier 34 of the power module 10. More specifically, the controller 44 may operate the AC power source 30, the drive board 40, and the energy storage device 32 to deliver the desired power to the energy storage device 32 from the AC power source 30 via the rectifier 34 of the power module 10. The power at various points within the system may be monitored and adjusted to obtain the desired power input from the AC power source 30 to the energy storage device 32. The AC power that is being delivered to the rectifier 34 from each winding phase 33 of the AC power source 30 may be determined by a fourth sensor 54 and a fifth sensor 56 that measure the alternating electric current being output from a first and second of the three winding phases 33, respectively, of the AC power source 30 and delivered to rectifier 34. The alternating electric current and power being input into the rectifier 34 from the third winding phase 33 of the AC power source 30 may be estimated based on the measurements of the first two winding phases 33. The direct electric current and power being output from the rectifier 34 and delivered to the energy storage device 32 may be determined by a sixth sensor 58 that measures the direct electric current being output from the rectifier 34. The first sensor 46, second sensor 50, third sensor 52, fourth sensor 54, fifth sensor 56, and sixth sensor 58 may all be hall-effect sensors.

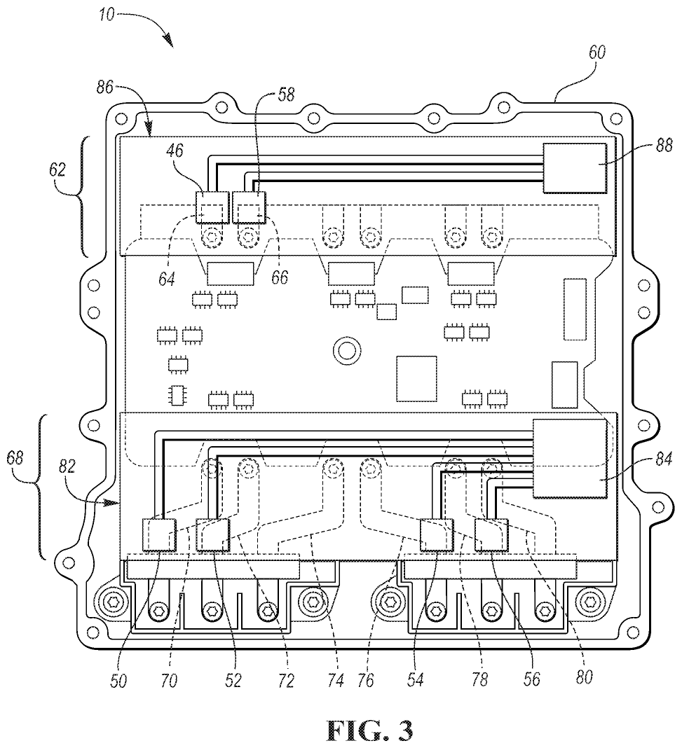

Referring to FIG. 3 a top view of a power module 10 that includes the inverting and rectifying circuitry is illustrated. The power module 10 includes a housing 60 that contains the inverting and rectifying circuitry. The power module includes a DC bus that 62 that connects the power source 12 to the inverter 16 and the energy storage device 32 to the rectifier 34. More specifically, a first terminal 64 is configured to connect the power source 12 to the inverter 16 and a second terminal 66 is configured to connect the energy storage device 32 to the rectifier 34. The first terminal 64 may be referred to as an input terminal to the inverter 16 because electricity flows into the inverter 16 from the power source 12. The second terminal 66 may be referred to as an output terminal of the rectifier 34 because electricity flows out of the rectifier 34 and into the energy storage device 32.

The power module includes an AC bus 68 that connects the inverter 16 to the electric machine 14 and the rectifier 34 to the AC power source 30. More specifically, a third terminal 70, a fourth terminal 72, and a fifth terminal 74 are each configured to connect each phase output of the inverter 16 to a respective one of the three winding phases 48 of the electric machine, and a sixth terminal 76, a seventh terminal 78, and an eighth terminal 80 are each configured to connect each winding phase 33 of the AC power source 30 to a respective one of the phase inputs to the rectifier 34. The third terminal 70, fourth terminal 72, and fifth terminal may be referred to as output terminals of the inverter 16 because electricity flows out of the inverter 16 and into the electric machine 14. The sixth terminal 76, seventh terminal 78, and eighth terminal 80 may be referred to as input terminals to the rectifier because electricity flows from the AC power source 30 and into the rectifier 34.

A first flexible circuit 82, which comprises a series of electrical circuits that are embedded in a flexible matrix such as a soft plastic or polymer, may have one or more sensors embedded therein that are configured to measure the magnitude of electric current flowing through an adjacent electrical component. For example, the second sensor 50, third sensor 52, fourth sensor 54, and fifth sensor 56 may be embedded in the first flexible circuit 82. The first flexible circuit 82 may include a logic circuit board 84 that communicates the magnitude of the electrical current readings from the sensors 50, 52, 54, 56 to the vehicle controller 44.

The first flexible circuit 82 may be secured to the AC bus 68 such that the second sensor 50 is disposed on the third terminal 70 (an output terminal of the inverter 16 that is connected to a first of the winding phases 48 of the electric machine 14) and the third sensor 52 is disposed on the fourth terminal 72 (an output terminal of the inverter 16 that is connected to a second of the winding phases 48 of the electric machine 14), so that the second sensor 50 and the third sensor 52 may measure the alternating electrical current being delivered from the inverter 16 to a first and a second of the winding phases 48 of the electric machine 14, respectively.

The first flexible circuit 82 may also be secured to the AC bus 68 such that fourth sensor 52 is disposed on the sixth terminal 76 (an input terminal to the rectifier 34 that is connected to a first of the winding phases 33 of the AC power source 30) and the fifth sensor 56 is disposed on the seventh terminal 78 (an input terminal to the rectifier 34 that is connected to a second of the winding phases 33 of the AC power source 30), so that the fourth sensor 52 and the fifth sensor 56 may measure the alternating electrical current being delivered to the rectifier 34 from a first and a second of the winding phases 33 of the AC power source 30, respectively.

The size and shape of the first flexible circuit 82 may be adjusted to the size and shape of the AC bus 68 depending on the design of the AC bus 68. The first flexible circuit 82 may include an adhesive layer that secures the first flexible circuit 82 to the AC bus 68. A back surface of the first flexible circuit 82 may include a “peel and stick” surface the comprises the adhesive layer and a removable backing, such as paper, that protects the adhesive layer prior to installation.

A second flexible circuit 86, which comprises a series of electrical circuits that are embedded in a flexible matrix such as a soft plastic or polymer, may have one or more sensors embedded therein that are configured to measure the magnitude of electric current flowing through an adjacent electrical component. For example, the first sensor 46 and the sixth sensor 58 may be embedded in the second flexible circuit 86. The second flexible circuit 86 may include a logic circuit board 88 that communicates the magnitude of the electrical current readings from the first sensor 46 and the sixth sensor 58 to the vehicle controller 44.

The second flexible circuit 86 may be secured to the DC bus 62 such that the first sensor 46 is disposed on the first terminal 64 (an input terminal to the inverter 16 from the power source 12), so that the first sensor 46 may measure the direct electrical current being delivered from the power source 12 to the inverter 16. The second flexible circuit 86 may also be secured to the DC bus 62 such that the sixth sensor 58 is disposed on the second terminal 66 (an output terminal of the rectifier 34 to the energy storage device 32), so that the sixth sensor 58 may measure the direct electrical current being delivered to the energy storage device 32 from the rectifier 24.

The size and shape of the second flexible circuit 86 may be adjusted to the size and shape of the DC bus 62 depending on the design of the DC bus 62. The second flexible circuit 86 may include an adhesive layer that secures the second flexible circuit 86 to the DC bus 62. A back surface of the second flexible circuit 86 may include a “peel and stick” surface the comprises the adhesive layer and a removable backing, such as paper, that protects the adhesive layer prior to installation. It should be understood that the designations of first, second, third, fourth, etc. for flexible circuits, sensors, winding phases, terminals, etc. or any other component, state, or condition described herein may be rearranged in the claims so that they are in chronological order with respect to the claims.

The words used in the specification are words of description rather than limitation, and it is understood that various changes may be made without departing from the spirit and scope of the disclosure. As previously described, the features of various embodiments may be combined to form further embodiments that may not be explicitly described or illustrated. While various embodiments could have been described as providing advantages or being preferred over other embodiments or prior art implementations with respect to one or more desired characteristics, those of ordinary skill in the art recognize that one or more features or characteristics may be compromised to achieve desired overall system attributes, which depend on the specific application and implementation. As such, embodiments described as less desirable than other embodiments or prior art implementations with respect to one or more characteristics are not outside the scope of the disclosure and may be desirable for particular applications.

What is claimed is:

1. A vehicle comprising:
an electric machine configured to propel the vehicle;
a battery;
an inverter configured to convert direct current from the battery into alternating current; and
a flexible circuit having a sensor embedded therein that is configured to measure a first phase of the alternating current, wherein the sensor is secured to an output terminal of the inverter that is connected to a first winding phase of the electric machine.

2. The vehicle of claim 1, wherein the flexible circuit has a second sensor embedded therein that is configured to measure a second phase of the alternating current, wherein the second sensor is secured to a second output terminal of the inverter that is connected to a second winding phase of the electric machine.

3. The vehicle of claim 1 further comprising a controller that is configured to adjust a power output of the electric machine, and wherein the flexible circuit is configured to communicate a magnitude of the first phase of the alternating current to the controller.

4. The vehicle of claim 1 further comprising a second flexible circuit having a second sensor embedded therein that is configured to measure the direct current of the battery, wherein the second sensor is secured to an input terminal of the inverter that is connected to the battery.

5. The vehicle of claim 4 further comprising a controller that is configured to adjust a power output of the electric machine, and wherein the second flexible circuit is configured to communicate a magnitude of the direct current of the battery to the controller.

6. The vehicle of claim 1, wherein the sensor is a hall-effect sensor.

7. The vehicle of claim 1, wherein sensor is secured to the output terminal of the inverter via an adhesive.

8. A vehicle comprising:
an electric machine configured to propel the vehicle;
a battery;
an inverter configured to convert direct current from the battery into alternating current; and
a flexible circuit having a sensor embedded therein that is configured to measure the direct current of the battery, wherein the sensor is secured to an input terminal of the inverter that is connected to the battery.

9. The vehicle of claim 8 further comprising a second flexible circuit having a second sensor embedded therein that is configured to measure a first phase of the alternating current, wherein the second sensor is secured to an output terminal of the inverter that is connected to a first winding phase of the electric machine.

10. The vehicle of claim 9, wherein the second flexible circuit has a third sensor embedded therein that is configured to measure a second phase of the alternating current, wherein the third sensor is secured to a second output terminal of the inverter that is connected to a second winding phase of the electric machine.

11. The vehicle of claim 9 further comprising a controller that is configured to adjust a power output of the electric machine, and wherein the second flexible circuit is configured to communicate a magnitude of the first phase of the alternating current to the controller.

12. The vehicle of claim 8 further comprising a controller that is configured to adjust a power output of the electric machine, and wherein the flexible circuit is configured to communicate a magnitude of the direct current of the battery to the controller.

13. The vehicle of claim 8, wherein the sensor is a hall-effect sensor.

14. The vehicle of claim 8, wherein the sensor is secured to the input terminal of the inverter via an adhesive.

15. A vehicle comprising:
an electric machine;
a battery;
a rectifier configured to convert alternating current from the electric machine into direct current; and
a flexible circuit having a sensor embedded therein that is configured to measure a first phase of the alternating current, wherein the sensor is secured to an input terminal of the rectifier that is connected to a first winding phase of the electric machine.

16. The vehicle of claim 15, wherein the flexible circuit has a second sensor embedded therein that is configured to measure a second phase of the alternating current, wherein the second sensor is secured to a second input terminal of the rectifier that is connected to a second winding phase of the electric machine.

17. The vehicle of claim 15 further comprising a controller that is configured to adjust a power output of the electric machine, and wherein the flexible circuit is configured to communicate a magnitude of the first phase of the alternating current to the controller.

18. The vehicle of claim 15 further comprising a second flexible circuit having a second sensor embedded therein that is configured to measure the direct current of the battery, wherein the second sensor is secured to an output terminal of the rectifier that is connected to the battery.

19. The vehicle of claim 18 further comprising a controller that is configured to adjust a power output of the electric machine, and wherein the second flexible circuit is configured to communicate a magnitude of the direct current of the battery to the controller.

20. The vehicle of claim 15, wherein the sensor is a hall-effect sensor.
